(19) United States
(12) Patent Application Publication
(10) Pub. No.: US 2024/0203747 A1
(43) Pub. Date: Jun. 20, 2024

(54) ISOTROPIC ECHING METHOD FOR TWO-DIMENSIONAL SEMICONDUCTOR MATERIALS

(71) Applicant: Research & Business Foundation SUNGKYUNKWAN UNIVERSITY, Suwon-si (KR)

(72) Inventors: Geun Young YEOM, Seoul (KR); Ji Eun KANG, Yongin-si (KR); Seong Jae YU, Suwon-si (KR); You Jin JI, Suwon-si (KR); Hye Won HAN, Suwon-si (KR); Ji Min KIM, Yongin-si (KR)

(73) Assignee: Research & Business Foundation SUNGKYUNKWAN UNIVERSITY, Suwon-si (KR)

(21) Appl. No.: 18/538,048

(22) Filed: Dec. 13, 2023

(30) Foreign Application Priority Data
Dec. 15, 2022 (KR) 10-2022-0176091

(51) Int. Cl. H01L 21/311; H01L 21/02

(52) U.S. Cl. CPC H01L 21/31122; H01L 21/02172; H01L 21/02244

(57) ABSTRACT

The present invention provides an isotropic etching method of two-dimensional semiconductor materials. The present invention provides an isotropic etching method of two-dimensional semiconductor materials including a first operation of arranging an etching object having a two-dimensional transition metal chalcogenide layer inside an etching space of a remote plasma system in which a discharge space and the etching space are separated, a second operation of extracting oxygen or halogen radical among plasma generated in the discharge space and reacting the two-dimensional transition metal chalcogenide layer with a surface to form an oxide layer and a radical adsorbate layer, and a third operation of selectively removing the oxide layer and the radical adsorbate layer in the etching space, wherein only an upper layer of the two-dimensional transition metal chalcogenide is precisely etched in units of atoms without defects and damage in a lower layer.

### CROSS-REFERENCE TO RELATED APPLICATION

The present application claims priority to Korean Patent Application No. 10-2022-0176091, filed on Dec. 15, 2022, the entire contents of which is incorporated herein for all purposes by this reference.

### BACKGROUND OF THE INVENTION

### Field of the Invention

The present invention relates to an isotropic etching method of two-dimensional semiconductor materials, and more specifically, to a method of selectively providing isotropic etching without defects in the two-dimensional semiconductor material film using a remote plasma system and an organic chemical vapor treatment method.

### Description of the Related Art

As the need for an increase in device integration to improve semiconductor performance and efficiency is increasing, major semiconductor companies around the world are focusing on developing ultra-fine processes. The smaller semiconductor circuits, the lower power consumption and the faster a processing speed, but as a size continuously decreases, there occurs a limit to decreasing an operation voltage, such as a problem that a gate may not be operated properly, and a leakage current is generated because a distance between a source and a drain becomes closer.

In order to improve this, three-dimensional structural processes are being developed. Among them, since a transistor having a next-generation 3-nano ‘gate-all-around (GAA)’ structure has a gate surrounding all four surfaces of a channel through which a current flows, there is an advantage in that it is possible to maximize a channel adjustment ability such as more precisely controlling a flow of a current and obtain high power efficiency. However, three-dimensional structured semiconductors require complicated and difficult process technologies such as precision etching and isotropic etching with ultra-high selectivity in order to avoid deforming or damaging an important film.

There are problems in that conventional dry etching methods are anisotropic etching methods, have low selectivity, and only one exposed surface is etched when applied to a three-dimensional structure, and when plasma is discharged for dry etching, ions generated from the plasma may physically collide to cause damage to a film, degrade semiconductor performance, and cause defects. In addition, even when wet etching rather than dry etching is applied for isotropic etching, there is a limit to an etching solution flowing into a pattern due to surface tension as the pattern becomes finer.

### SUMMARY OF THE INVENTION

The present invention is directed to providing an isotropic etching method of precisely etching only upper portions of atomic layers of two-dimensional semiconductor materials.

The present invention is also directed to providing an isotropic etching method of etching a fine pattern in a three-dimensional structure without damage or defects in two-dimensional semiconductor materials.

An isotropic etching method of two-dimensional semiconductor materials for achieving the objects of the present invention includes a first operation of arranging an etching object having a two-dimensional transition metal chalcogenide layer inside an etching space of a remote plasma system in which a discharge space and the etching space are separated, a second operation of extracting (oxygen or halogen) radical among plasma generated in the discharge space and reacting the two-dimensional transition metal chalcogenide layer with a surface to form an oxide layer or a radical adsorbed layer, and a third operation of selectively removing the oxide layer or the radical adsorbed layer in the etching space.

In one embodiment, the third operation may include a process of selectively etching the oxide layer or the radical adsorbed layer by vaporizing a liquid organic solvent containing a carbonyl group and a carboxyl group and supplying the vaporized organic solvent to the inside of the etching space.

In one embodiment, the third operation may include a process of selectively etching the oxide layer by extracting halogen radicals from the plasma and reacting the halogen radicals with the oxide layer or the radical adsorbed layer.

In one embodiment, the halogen radical may be any one selected from the group consisting of fluorine (F), chlorine (Cl), bromine (Br), and iodine (I).

In one embodiment, the organic solvent may be any one selected from the group consisting of formic acid, acetylacetone, hexafluoroacetylacetone, ethylenediamineteraacetic acid (EDTA), nitrilotriacetic acid, pyridine-2,6-dicarboxylic acid (PDCA), and oxalic acid.

In one embodiment, the two-dimensional transition metal chalcogenide may be any one selected from the group consisting of MoS₂, MoSe₂, WS₂, WSe₂, TiS₂, TiSe₂, TiTe₂, HfS₂, HfSe₂, HfTe₂, ZrS₂, ZrSe₂, ZrTe₂, TcS₂, TcSe₂, TcTe₂, ReS₂, ReSe₂, ReTe₂, PdS₂, PdSe₂, PtS₂, and PtSe₂.

In one embodiment, in the third operation, the organic solvent may be vaporized by a heating system.

In one embodiment, in the third operation, a vaporized organic solvent together with a carrier gas may be supplied to the inside of the etching space.

In one embodiment, the carrier gas may be any one selected from the group consisting of nitrogen, argon, helium, and neon.

In one embodiment, a cycle consisting of the second operation and the third operation may be performed multiple times.

### BRIEF DESCRIPTION OF THE DRAWINGS

FIG. 1 is a view illustrating an apparatus for an isotropic etching method of two-dimensional semiconductor materials according to one embodiment of the present invention.

FIG. 2 is a flowchart illustrating the isotropic etching method of the two-dimensional semiconductor materials according to the present invention.

FIG. 3 is a view for describing an isotropic etching process of a transition metal chalcogenide in a gate-all-around (GAA) structure.

FIG. 4 is a view illustrating results of measuring optical microscope images (A/B), sample step (C/D), and surface roughness (E/F) of PdSe₂ before and after etching through the isotropic etching method of two-dimensional semiconductor materials according to one embodiment of the present invention (a left image is before etching, and a right image is after etching).

FIG. 5a is a view illustrating results (Binding energy 332-348) of analyzing components of PdSe₂ before etching, after oxidation treatment, and after organic chemical vapor treatment through an X-ray photoelectron spectroscopy (XPS) (before etching is marked as “reference”, after oxidation treatment is marked as “oxidation”, and after organic chemical vapor treatment is marked as “formic acid”).

FIG. 5b is a view illustrating results (Binding energy 50-64) of analyzing components of PdSe₂ before etching, after oxidation treatment, and after organic chemical vapor treatment through an X-ray photoelectron spectroscopy (XPS) (before etching is marked as “reference”, after oxidation treatment is marked as “oxidation”, and after organic chemical vapor treatment is marked as “formic acid”).

FIG. 5c is a view illustrating results (Binding energy 50-350) of analyzing components of PdSe₂ before etching, after oxidation treatment, and after organic chemical vapor treatment through an X-ray photoelectron spectroscopy (XPS) (before etching is marked as “reference”, after oxidation treatment is marked as “oxidation”, and after organic chemical vapor treatment is marked as “formic acid”).

FIG. 6 is a view illustrating results of analyzing the components after oxidation treatment and high temperature treatment except for organic chemical vapor treatment through the XPS (before treatment is marked as “reference”, and after oxidation treatment and high temperature treatment are marked as “oxidation+annealing”).

FIG. 7 is a view illustrating results of analyzing that the number of layers of PdSe₂ decreases as many as the number of cycles as the cycle is repeated through transmission electron microscopy (TEM).

### DETAILED DESCRIPTION OF THE INVENTION

Hereinafter, embodiments of the present invention will be described in detail with reference to the accompanying drawings. Since the present invention can be variously modified and may have various forms, specific embodiments will be illustrated in drawings and described in detail in the detailed description. However, it should be understood that this is not intended to limit the present invention to a specific disclosed form and includes all changes, equivalents, and substitutions included in the spirit and technical scope of the present invention. Like reference numerals have been used for like components throughout the description of each drawing.

The terms used in the present application are only used to describe specific embodiments and are not intended to limit the present invention. The singular expression includes the plural expression unless the context clearly dictates otherwise. In the present application, it should be understood that terms such as “comprise” or “have” are intended to specify that a feature, a number, a step, an operation, a component, a part, or a combination thereof described in the specification is present, but do not preclude the possibility of the presence or addition of one or more other features, numbers, steps, operations, components, parts, or combinations thereof.

Unless defined otherwise, all terms used herein, including technical or scientific terms, have the same meaning as commonly understood by those of ordinary skill in the art to which the present invention pertains. Terms such as those defined in a commonly used dictionary should be construed as having a meaning consistent with the meaning in the context of the related art and should not be construed in an ideal or excessively formal meaning unless explicitly defined in the application.

In the present invention, “isotropic etching” means that etching is performed equally in all directions. Conversely, “anisotropic etching” means that etching is performed only in a specific direction.

Since a silicon or metal-based bulk material, which is a conventional semiconductor material, has a bulk form with strong covalent bonds between atoms, a certain degree of surface damage or change in thickness during etching does not significantly affect changes in material properties. Meanwhile, a two-dimensional transition metal chalcogenide with a thickness of several nm is greatly affected by surface damage when etched by conventional technologies because a change in one atomic layer is directly related to changes in material properties such as a change in band gap, and it is very important to precisely etch only an upper layer without a change in lower layer. Therefore, the present invention aims to provide a defect-free isotropic etching method for applying the two-dimensional transition metal chalcogenide to a three-dimensional device structure without surface damage.

In the present invention, the two-dimensional transition metal chalcogenide was etched precisely in units of atoms by changing only an upper atomic layer of the two-dimensional transition metal chalcogenide to weakening binding using the property that atoms are bound by very strong covalent bonds in one atomic layer but the atoms are bound by very weak van der Waals interaction, and used a plasma system and a high-temperature environment together to prevent a lower layer from being damaged or etched. When only plasma is used, a physical impact caused by ions may be transmitted to the lower atomic layer, and when only temperature control is used, a high-temperature environment may change a structure and characteristics of the lower layer, and thus the present invention is characterized by using them together.

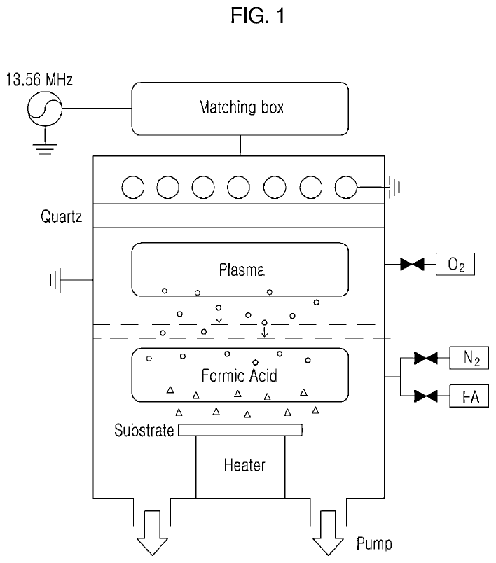

FIGS. 1 to 3 are views for describing an isotropic etching method of two-dimensional semiconductor materials according to one embodiment of the present invention.

Referring to FIG. 1, the isotropic etching method of two-dimensional semiconductor materials according to the present invention is characterized by using a remote plasma system. The remote plasma system may have a structure in which an etching space in which actual etching is performed and a discharge space in which plasma is generated are separated. For example, the etch space and the discharge space may each have a separate structure in a different chamber or have a structure separated through a structure in one chamber. Various plasma species including ions, electrons, radicals, and the like are generated in the discharge space, and in the remote plasma system, not all plasma species present in the discharge space reach the etch space due to the separated space structure. The present invention is characterized by using reactive oxygen or halogen radical among the plasma species. In one embodiment, the remote plasma system may include a structure having a through hole through which only oxygen or halogen radical may selectively pass in order to selectively supply the oxygen or halogen radical to the etching space, and the discharge space and the etch space may be distinguished by the structure. In another embodiment, the remote plasma system may include a structure having through holes through which radicals of different species may selectively pass to supply different types of radicals to the etch space. A source of the remote plasma system may be a microwave source or RF source. However, the present invention is not particularly limited thereto.

Specifically, the isotropic etching method of the two-dimensional semiconductor material according to the present invention includes a first operation of arranging an etching object having a two-dimensional transition metal chalcogenide layer inside the etching space of a remote plasma system in which the discharge space and the etching space are separated, a second operation of extracting oxygen or halogen radical from the plasma generated in the discharge space and reacting the transition metal chalcogenide layer on a surface to form an oxide layer or radical adsorbed layer, and a third operation of selectively removing the oxide layer or radical adsorbed layer.

During the second operation, all exposed surfaces of the transition metal chalcogenide may react with the oxygen or halogen radical to form the oxide layer or radical adsorbed layer on all exposed surfaces. A thickness of the oxide layer may be controlled according to a condition in which the second operation is performed. Preferably, the thickness of the oxide layer may be in a range of 0.5 to 1 nm. There is a problem that the oxide layer is excessively etched or may not be fully etched within a reaction time when the oxide layer is too thick, and there is a problem that one atomic layer may not be completely removed when the oxide layer is too thin. In the case of the radical adsorbate layer, radicals may be adsorbed only on the surface of the transition metal chalcogenide.

In one embodiment, the third operation may include a process of selectively etching the oxide layer or the radical adsorbed layer by vaporizing a liquid organic solvent containing a carbonyl group and a carboxyl group and supplying the vaporized organic solvent to the inside of the etching space. During the third operation, the oxide layer or the radical adsorbed layer may react with the vaporized organic solvent to form a complex. The formed complex is stable and highly volatile. Therefore, the oxide layer or the radical adsorbed layer may react with the vaporized organic solvent to form the complex during the third operation to be etched by being evaporated and removed. In this case, the complex may be formed by the carbonyl group and carboxyl group, which are the organic ligand. In other words, the oxygen radical forming the oxide or the radical adsorbed on the surface of the transition metal chalcogenide functions to allow the carbonyl group and carboxyl group of the organic solvent to be easily bound with the material to form the complex.

The organic solvent may be any one selected from the group consisting of formic acid, acetylacetone, hexafluoroacetylacetone, ethylenediamineteraacetic acid (EDTA), nitrilotriacetic acid, pyridine-2,6-dicarboxylic acid (PDCA), and oxalic acid. According to the present invention, it is possible to reduce physical impacts and process temperatures using the chemical reaction through the use of the organic solvent, which is a very important configuration for etching the transition metal chalcogenide without defects. In the present invention, the type of organic solvent is not particularly limited, and any organic solvent containing a carbonyl group and a carboxyl group can be used.

The organic solvent may be vaporized by a heating system or vaporized by a bubbling method using a carrier gas. In the present invention, the method of vaporizing the organic solvent is not particularly limited. In one embodiment, the organic solvent may be vaporized by the heating system. Specifically, the heating system may include a canister having a liquid organic solvent therein and a supply line connecting the canister to the etching space. The vaporization of the organic solvent may be performed by heating the canister and the supply line, and the vaporized organic solvent may be supplied to the etching space through the supply line.

In the third operation, the vaporized organic solvent together with the carrier gas may be supplied to the inside of the etching space. For example, the carrier gas may be any one selected from the group consisting of nitrogen, argon, helium, and neon.

Meanwhile, in another embodiment, the third operation may include a process of selectively etching the oxide layer by extracting halogen radical from the plasma and reacting the halogen radical with the oxide layer. When the halogen radical reacts with the oxide layer to form an oxyhalide group, a vapor pressure becomes higher than that of a simple oxide or simple halogen compound, and the halogen radical may be easily removed at a lower temperature.

In one embodiment, the halogen radical may be any one selected from fluorine (F), chlorine (Cl), bromine (Br), and iodine (I).

In the third operation, a temperature of the substrate on which the etching object is positioned may be set depending on the type of the transition metal chalcogenide, and preferably, the temperature of the substrate may be in a range of 50 to 700° C. The temperature of the substrate may be adjusted through a heater connected to the substrate, and in the third operation, when the temperature of the substrate is increased and the substrate temperature reaches a set value, the organic solvent is supplied to the inside of the etching space, but if necessary, the temperature is increased and then continuously maintained after the first operation, and etching may be performed by repeatedly performing the second and third operations.

The transition metal chalcogenide can be represented by a chemical formula MX₂.

Here, M denotes a transition metal element and X denotes a chalcogen element. In one embodiment, the two-dimensional transition metal chalcogenide may be any one selected from the group consisting of MoS₂, MoSe₂, WS₂, WSe₂, TiS₂, TiSe₂, TiTe₂, HfS₂, HfSe₂, HfTe₂, ZrS₂, ZrSe₂, ZrTe₂, TcS₂, TcSe₂, TcTe₂, ReS₂, ReSe₂, ReTe₂, PdS₂, PdSe₂, PtS₂, and PtSe₂.

In addition, in the present invention, the combination of the transition metal chalcogenide and the organic solvent used are not particularly limited.

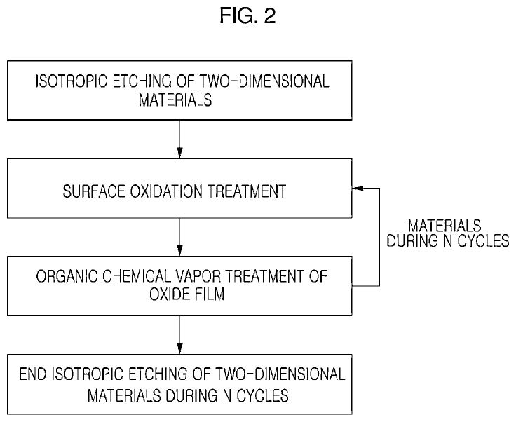

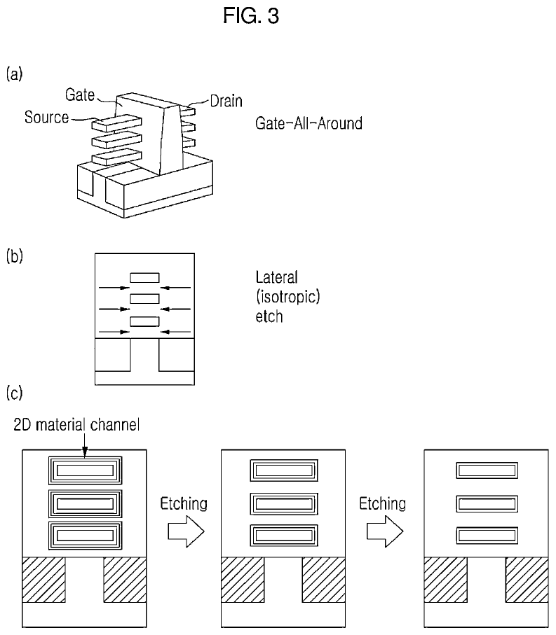

Meanwhile, referring to FIGS. 2 and 3, in the present invention, a cycle consisting of the second and third operations may be performed multiple times in order to etch the transition metal chalcogenide layer to a desired thickness. In particular, referring to FIG. 3, it can be seen that as the manufacturing method of the present invention is performed multiple times, a device having a three-dimensional structure, such as a GAA, may be manufactured precisely with the two-dimensional transition metal chalcogenide material.

Hereinafter, an example of the present invention will be described. However, the example described below is only one of examples of the present invention, and the scope of the present invention is not limited to the following example.

### 1. Example

PdSe₂ was used as the transition metal chalcogenide, and formic acid was used as the organic solvent. The oxidation process was performed in the remote plasma system under a condition of 100 mTorr and 300 W for 10 min, and the organic solvent treatment was performed under a condition of 5 Torr and 290° C. for 1 min. The above process was set to 1 cycle, and etching was performed by about 0.5 to 7 nm per cycle.

### 2. Analysis Result

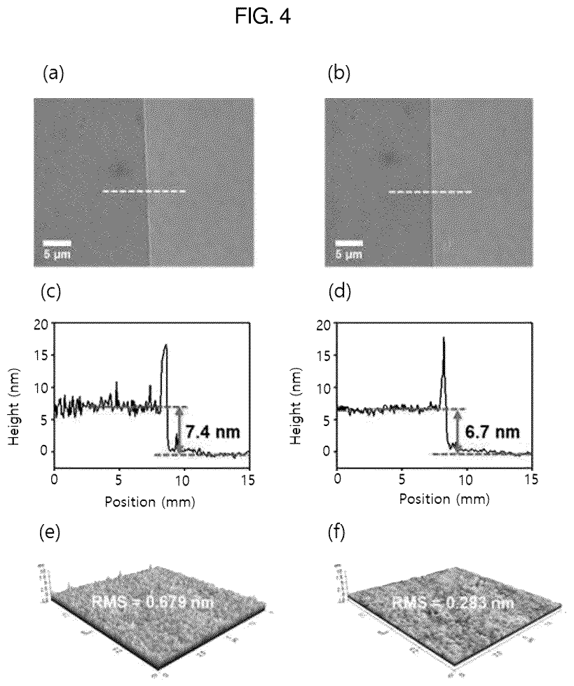

FIG. 4 is a view illustrating results of measuring optical microscope images, sample step, and surface roughness of PdSe₂ before and after etching through the isotropic etching method of two-dimensional semiconductor materials according to one embodiment of the present invention (a left image is before etching, and a right image is after etching).

Referring to FIG. 4, it can be seen that a thickness of one atomic layer of PdSe₂ is reduced after one cycle of the etching process (thickness of one layer of the two-dimensional material: 0.5 to 0.9 nm). In addition, it can be seen that the surface roughness is also improved after treatment. This may mean that no damage was caused to PdSe₂ during the etching process.

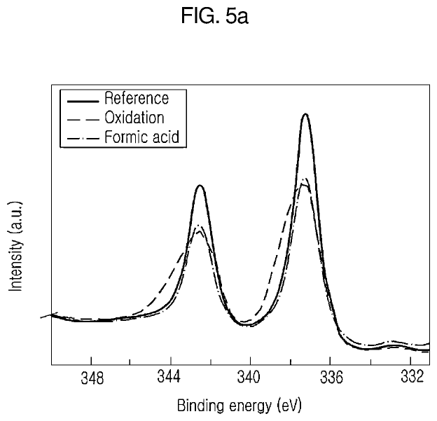

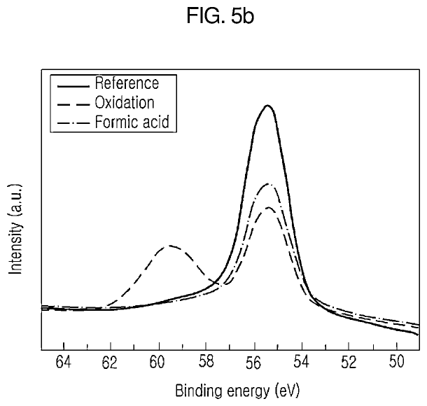

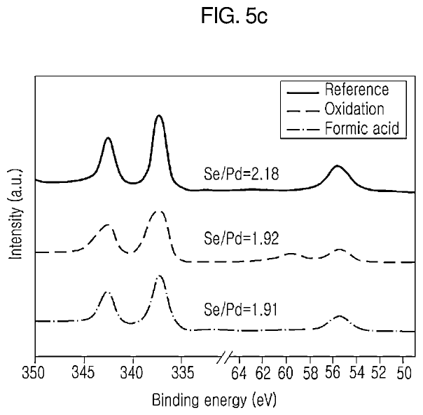

FIG. 5 is a view illustrating results of analyzing components of PdSe₂ before etching, after oxidation treatment, and after organic chemical vapor treatment through an X-ray photoelectron spectroscopy (XPS).

Referring to FIG. 5, it can be seen that Pd—O and Se—O oxidation peaks measured after oxidation treatment do not appear after organic chemical vapor treatment. Therefore, it can be seen that the oxide layers formed on PdSe₂ were all removed by being reacted with the organic solvent. In addition, it can be seen that since a Se/Pd ratio is maintained at about 2, the etching process did not cause defects in the material and PdSe₂ was removed at a certain percentage.

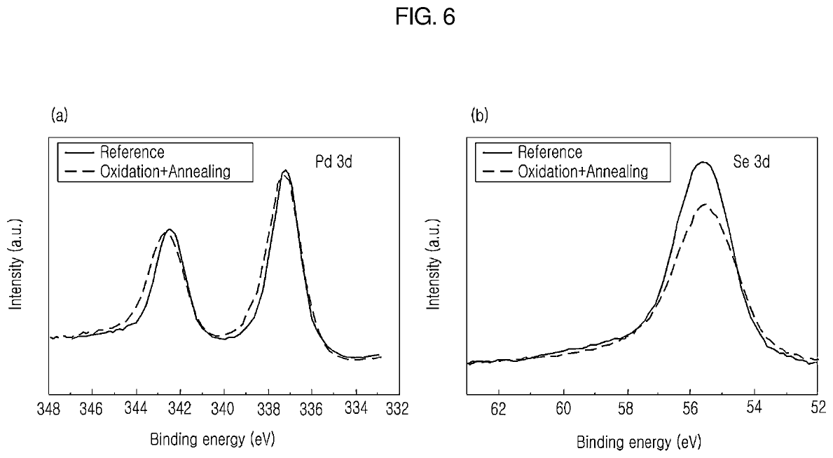

FIG. 6 is a view illustrating results of analyzing the components of PdSe₂ before treatment, oxidation treatment, and high-temperature treatment through the XPS.

Referring to FIG. 6, it can be seen that when only the oxidation treatment and the high-temperature treatment except for the organic chemical vapor treatment were performed, Pd was not removed, and only Se was removed. It can be seen that when the Se/Pd ratio was calculated, the ratio was a value close to 2 before treatment, and then decreased to 1.48 after treatment, and thus only Se was removed, and the ratio was decreased.

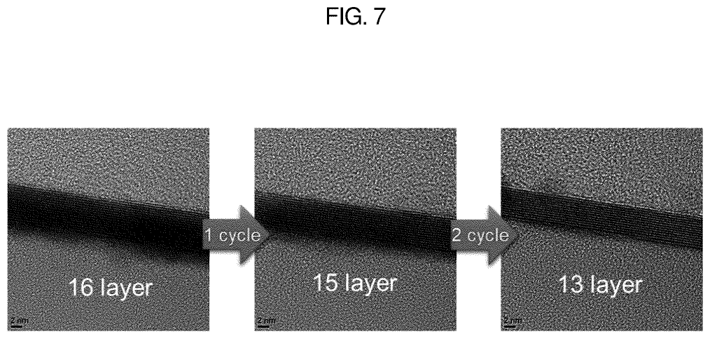

FIG. 7 is a view illustrating results of analyzing that the number of layers of PdSe₂ decreases as many as the number of cycles as the cycle is repeated through transmission electron microscopy (TEM).

Referring to FIG. 7, one layer of 16 layers of PdSe₂ before cycle treatment was removed after 1 cycle to become 15 layers, and after additional 2 cycles, that is, after a total of 3 cycles, 3 layers of PdSe₂ were removed to become 13 layers, and thus it can be seen that one layer per cycle was precisely etched.

According to the present invention, it is possible to easily apply the two-dimensional semiconductor materials to the manufacturing process of the next-generation semiconductor device and perform the selective isotropic etching for the two-dimensional semiconductor materials without defects in the film.

Although the present invention has been described above with reference to preferred embodiments, those skilled in the art will understand that the present invention may be modified and changed variously without departing from the spirit and scope of the present invention as described in the appended claims.

What is claimed is:

1. An isotropic etching method of two-dimensional semiconductor materials, the method comprising:
a first operation of arranging an etching object having a two-dimensional transition metal chalcogenide layer inside an etching space of a remote plasma system in which a discharge space and the etching space are separated;
a second operation of extracting oxygen or halogen radical among plasma generated in the discharge space and reacting the two-dimensional transition metal chalcogenide layer with a surface to form an oxide layer or a radical adsorbate layer; and
a third operation of selectively removing the oxide layer or the radical adsorbed layer in the etching space.

2. The method of claim 1, wherein the third operation includes a process of selectively etching the oxide layer or the radical adsorbed layer by vaporizing a liquid organic solvent containing a carbonyl group or a carboxyl group and supplying the vaporized organic solvent to the inside of the etching,

3. The method of claim 1, wherein the third operation includes a process of selectively etching the oxide layer by extracting halogen radical from the plasma and reacting the halogen radical with the oxide layer or the radical adsorbed layer.

4. The method of claim 3, wherein the halogen radical is any one selected from the group consisting of fluorine (F), chlorine (Cl), bromine (Br), and iodine (I).

5. The method of claim 2, wherein the organic solvent is any one selected from the group consisting of formic acid, acetylacetone, hexafluoroacetylacetone, ethylenediamineteraacetic acid (EDTA), nitrilotriacetic acid, pyridine-2,6-dicarboxylic acid (PDCA), and oxalic acid.

6. The method of claim 1, wherein the two-dimensional transition metal chalcogenide is any one selected from the group consisting of MoS₂, MoSe₂, WS₂, WSe₂, TiS₂, TiSe₂, TiTe₂, HfS₂, HfSe₂, HfTe₂, ZrS₂, ZrSe₂, ZrTe₂, TcS₂, TcSe₂, TcTe₂, ReS₂, ReSe₂, ReTe₂, PdS₂, PdSe₂, PtS₂, and PtSe₂.

7. The method of claim 2, wherein in the third operation, the organic solvent is vaporized by a heating system.

8. The method of claim 2, wherein in the third operation, a vaporized organic solvent together with a carrier gas is supplied to the inside of the etching space.

9. The method of claim 8, wherein the carrier gas is any one selected from the group consisting of nitrogen, argon, helium, and neon.

10. The method of claim 1, wherein a cycle consisting of the second operation and the third operation is performed multiple times.
